(19) United States
(12) Patent Application Publication
(10) Pub. No.: US 2004/0016924 A1
(43) Pub. Date: Jan. 29, 2004

(54) Top gate type thin film transistor

(76) Inventors: Tsutomu Yamada, Motosu-gun (JP); Yasuo Segawa, Gifu-shi (JP); Masaaki Aota, Ohgaki-shi (JP)

Correspondence Address: CANTOR COLBURN, LLP, 55 GRIFFIN ROAD SOUTH, BLOOMFIELD, CT, 06002

(21) Appl. No.: 10/384,854

(22) Filed: Mar. 10, 2003

(30) Foreign Application Priority Data
Mar. 11, 2002 (JP) 2002-65803

(51) Int. Cl. H01L 29/04; H01L 31/036

(52) U.S. Cl. 257/59; 257/72

(57) ABSTRACT

In a top gate type TFT wherein a gate electrode is formed above an active layer, an interlayer insulating film formed so as to cover a TFT active layer, a gate insulating film, and a gate electrode have a structure configured by laminating a SiNₓ film and a SiO₂ film, in that order from an active layer side. The thickness of the SiNₓ film is between 50 nm-200 nm, more preferably on the order of 100 nm. Employing such a thickness ensures that a sufficient amount of hydrogen for terminating dangling bonds can be supplied to the active layer made of a semiconductor such as polycrystalline Si provided as a lower layer. Further, a higher accuracy of contact holes or the like formed in the interlayer insulating film can be assured.

### BACKGROUND OF THE INVENTION

1. Field of the Invention

The present invention relates to a top gate type thin film transistor and more particularly to a structure of an insulating film of a top gate type thin film transistor.

2. Description of the Related Art

Commonly used liquid crystal display (LCD) apparatuses and the more recently developed organic electroluminescence (OEL) display apparatuses are both commonly formed as active matrix displays, that is, display apparatuses wherein a switching element is formed for each pixel in order to realize high definition display.

As the switching element for a pixel of the active matrix display apparatus, a thin film transistor (hereinafter referred to as TFT) is also well known. Among such thin film transistors, a polycrystalline Si-TFT using polycrystalline silicon (p-Si) in an active layer can realize higher conductivity, thereby achieving quick response as compared with when amorphous silicon (a-Si) is used in the active layer. In a polycrystalline Si-TFT, channel, source, and drain regions can be formed on the active layer so as to be self aligned using a gate electrode, which enables minimization of an element area and easy configuration of a CMOS (Complementary Metal Oxide Semiconductor) circuit. Accordingly, the polycrystalline Si-TFT can optimally work as an excellent switch for high resolution display. Further, it is also possible to provide an integral driver circuit for driving a display portion by forming the CMOS circuit configured by a similar TFT on the substrate on which the TFT for pixel is formed.

A polycrystalline Si film can be obtained by forming an amorphous silicon (a-Si) film and polycrystallizing the a-Si film by laser annealing. A TFT using the thus-formed polycrystalline Si film as an active layer can be configured on a low-cost glass substrates having a low melting point. Such formability very effectively contributes to obtaining low-cost active matrix flat display apparatuses having a large screen area.

The polycrystalline Si film formed through a process wherein laser annealing and other subprocesses are executed as described above, in other words, through a low-temperature process, includes a large number of unpaired electron pairs of silicon in grain boundaries or the like within the film. Dangling bonds could cause reduced conductivity and/or generation of leakage current while the TFT is OFF by trapping carriers. Accordingly, in the art of manufacturing a polycrystalline Si film, hydrogenation for terminating the dangling bonds in the film by hydrogen is well known.

In a TFT of the so-called top gate type, which is one possible structure for TFTs, an active layer is covered with a gate insulating film on which a gate electrode is formed. For hydrogenation of the polycrystalline Si film of the top gate type TFT, a SiO₂ film formed by a plasma CVD method in which hydrogen can be introduced into the film is used as an interlayer insulating film covering a gate insulating film and the gate electrode. More specifically, after the formation of the SiO₂ film by the plasma CVD method, hydrogenation of the polycrystalline Si film is typically performed by proving hydrogen from the SiO₂ interlayer insulating film to the polycrystalline Si film through the gate insulating film by annealing for hydrogenation. However, there is a problem that the capacity of the SiO₂ interlayer insulating film as a hydrogen source is insufficient. Although hydrogen plasma treatment can be applied when the SiO₂ film is formed in order to enhance the ability of the film to supply hydrogen, because the cycle time of the treatment is long, the hydrogen plasma treatment is undesirable in terms of efficiency and cost of manufacture.

Although the SiO₂ film is usually provided in a single layer as the gate insulating film covering the active layer, it is also possible to employ a laminated structure of the SiO₂ film and a silicon nitride (SiNₓ) film having high supply capability of hydrogen to the gate insulating film. The hydrogen content in the silicon nitride film acting as the hydrogen source increases as the thickness of the silicon nitride film increases. Accordingly, as s hydrogen source, a thicker silicon nitride film is more desirable. However, because the increased thickness of the gate insulating film causes problems, such as fluctuation (increase) of operation threshold of the TFT, other design considerations make it impossible to secure a sufficient thickness of the gate insulating film as a hydrogen source.

It should be noted that if the interlayer insulating film is formed in the laminated structure of the SiO₂ film and the SiNₓ film, as with a bottom gate type TFT, conditions for supplying hydrogen differ between the top gate type TFT and the bottom gate type TFT because, intervening between the interlayer insulating film and the polycrystalline Si film, the gate insulating film is provided and, in same positions, the gate electrode is provided in the top gate type TFT as described above.

Now, there is no suggestion concerning appropriate supply conditions for good hydrogenation with regard to such top gate type TFTs. It is therefore strongly desired that the supply conditions be optimized.

### SUMMARY OF THE INVENTION

According to the present invention, characteristics of top gate type thin film transistors as described above can be improved.

In order to achieve such improvement, the present invention provides a top gate type thin film transistor wherein a gate electrode is formed above an active layer, and the top gate type thin film transistor comprises a semiconductor film formed on a substrate, a gate insulating film covering the semiconductor film, a gate electrode formed on the gate insulating film, and an interlayer insulating film formed so as to cover the gate electrode and the gate insulating film. Further, the interlayer insulating film has a multilayer structure in which a silicon nitride film and a silicon oxide film are formed, in that order from a gate insulating film side, and the thickness of the silicon nitride film is greater than or equal to 50 nm and smaller than or equal to 200 nm.

According to one aspect of the present invention, in the top gate type thin film transistor, thickness of the silicon nitride film is approximately 100 nm.

According to another aspect of the present invention, the silicon nitride film acts as a hydrogen source for the semiconductor film made of polycrystalline silicon.

By placing the silicon nitride film formed with the above thickness on the gate insulating film side of the interlayer insulating film, a sufficient amount of hydrogen for terminating dangling bonds in the active layer made of polycrystalline silicon or the like and other layers can be provided to the active layer from the silicon nitride film. By forming the silicon nitride film with the above-described thickness, when a contact hole is formed in the interlayer insulating film, formation accuracy can be secured, and adaptation to denser and higher-definition contact can be achieved.

According to still another aspect, the present invention relates to a top gate type thin film transistor wherein a gate electrode is formed above an active layer, the top gate type thin film transistor comprising a buffer layer formed so as to cover a substrate, a semiconductor film formed on the buffer layer, a gate insulating film covering the semiconductor film, a gate electrode formed on the gate insulating film, and an interlayer insulating film formed so as to cover the gate electrode and the gate insulating film. Further, the buffer layer has a multilayer structure in which a silicon nitride film and a silicon oxide film are formed in that order from a substrate side, the gate insulating film has a multilayer structure in which the silicon oxide film and the silicon nitride film are formed in that order from a semiconductor side, and the interlayer insulating film has a multilayer structure in which the silicon nitride film and the silicon oxide film are formed in that order from a gate insulating film side.

According to a further aspect of the present invention, in the top gate type thin film transistor, the thickness of the silicon nitride film constituting the interlayer insulating film is within the range of 50 nm to 200 nm.

By forming the buffer layer, the gate insulating film and the interlayer insulating film in the multilayer structure and defining the films as a combination of the silicon nitride film and the silicon oxide film formed in the optimum order, operating characteristics and reliability of the transistor can be improved and a top gate type thin film transistor having high integration density can be realized. More specifically, the silicon nitride films provided at both upper and lower positions of the thin film transistor can reliably prevent impurities from diffusing in the thin film transistor. Further, because the silicon nitride films acting as hydrogen sources and each constituting the interlayer insulating film and the gate insulating film are located near the polycrystalline silicon active layer of the thin film transistor, hydrogen can be efficiently supplied to polycrystalline silicon. When the gate insulating film has a multilayer structure in which a relatively fine silicon nitride film is formed, the insulating performance of the thin film transistor can be improved. By also forming the inter layer insulating film with a multilayer structure in which the silicon nitride film is formed, the capability for blocking contaminants from entering the gate insulating film can be further improved. Further, when amorphous silicon is laser annealed to obtain polycrystalline silicon, margins of output intensity of laser light and so on can be increased because the buffer layer is provided under the silicon film, thereby achieving reliable control of the operation threshold (Vth) of the thin film transistor. Further, it is possible to adjust color tint in a display apparatus employing the buffer layer, which contributes to improving the quality of the display apparatus.

### BRIEF DESCRIPTION OF THE DRAWINGS

FIG. 1 is a cross-sectional view showing a schematic structure of a thin film transistor according to a first embodiment of the present invention;

FIGS. 2A, 2B, 2C, 2D, and 2E are diagrams illustrating a process for manufacturing the thin film transistor illustrated in FIG. 1;

FIG. 3 is a diagram showing the relationship between the thickness of an SiNₓ film constituting an interlayer insulating film according to the embodiment of the present invention and operation threshold of a p-ch TFT;

FIG. 4 is a diagram showing the relationship between the thickness of an SiNₓ film constituting an interlayer insulating film according to the embodiment of the present invention and CD loss;

FIG. 5 is a diagram showing a cross-sectional shape of a contact hole formed penetrating the interlayer insulating film, and

FIG. 6 is a cross-sectional view showing a schematic structure of a thin film transistor according to a second embodiment of the present invention.

### DESCRIPTION OF THE PREFERRED EMBODIMENTS

Preferred embodiments of the present invention will be described below referring to drawings.

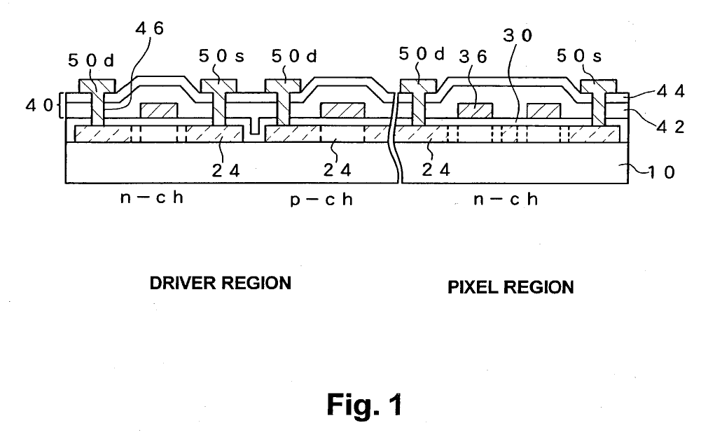

FIG. 1 shows a cross-sectional structure of a TFT according to a first embodiment of the present invention. It should be noted that, as shown in FIG. 1, the TFT may be used as a pixel TFT working as a switching element which is adopted in each pixel of an active matrix display apparatus (LCD, OLE display apparatus, or the like), or may be used as TFTs to be a CMOS structure of a driver circuit which is formed concurrently with the switching element on the substrate where the switching element is formed.

The TFT according to the present embodiment is a top gate type TFT wherein a gate electrode 36 is formed above an active layer 24 and a multilayer film of a SiNₓ film 42 and a SiO₂ film 44 is formed as an interlayer insulating film 40 covering a gate insulating film 30 and the gate electrode 36. Further, the SiNₓ film 42 placed on a gate insulating film 30 side and acting as a supply source of hydrogen for the active layer 24 is formed with a thickness within the bounds of 50 nm-200 nm, more preferably on the order of 100 nm.

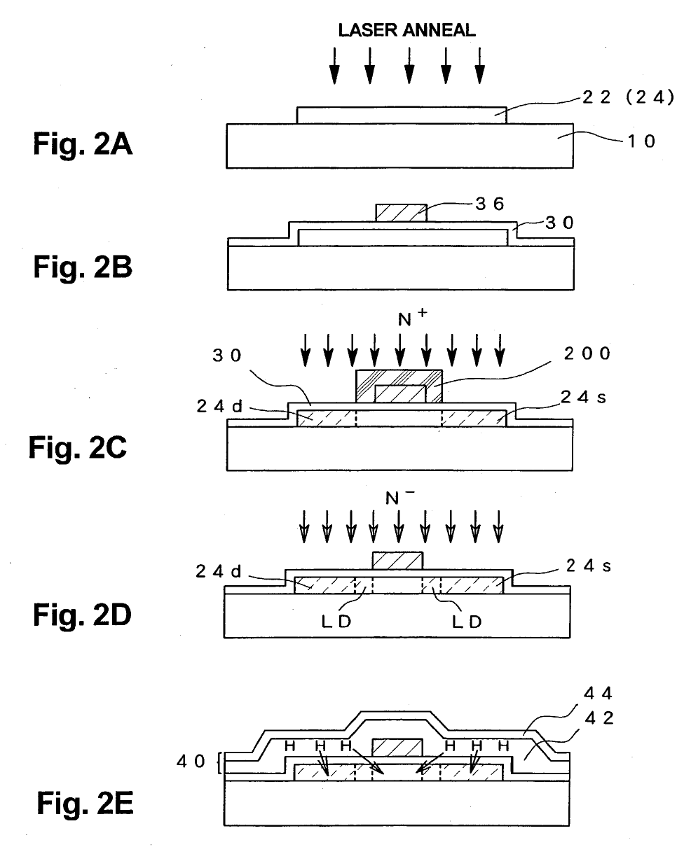

FIGS. 2A to 2E show a manufacturing process for forming such a TFT. This process will now be described with reference to this figures and to FIG. 1. As a substrate for forming the TFT, an insulating substrate or a semiconductor substrate may be used. In this embodiment, however, a transparent glass substrate 10 having a low melting point is adopted. A pattern of the active layer made of polycrystalline Si of the TFT is formed over the glass substrate 10. More specifically, as shown in FIG. 2A, an a-Si film 22 having a thickness of approximately 40 nm-50 nm is formed on the glass substrate 10. In order to prevent occurrence of ablation during a subsequent annealing process, the a-Si film 22 is subjected to annealing for dehydrogenation, and then the a-Si film 22 is subjected to annealing for polycrystallization by irradiation with an excimer laser beam. The resulting polycrystalline Si film obtained by annealing is patterned in the shape desired for the active layer 24 of the TFT.

Next, the gate insulating film 30 made of SiO₂ is formed so as to cover the active layer 24 as shown in FIG. 2B. A gate electrode material made of refractory metal, such as Cr, is formed on the gate insulating film 30 and then patterned in a desired shape of the gate electrode 36.

When the TFT is a n conductive TFT (hereinafter referred to as an n type TFT) and a LDD (Lightly Doped Drain) is formed, a resist layer 200 is selectively left by photolithography so as to cover the gate electrode 36 including predetermined-length outer regions (in a lateral direction of the drawing) of the gate electrode 36 as shown in FIG. 2C. When a driver circuit is integral with the substrate where the TFT of the pixel region is formed, the active layer of a p channel TFT for a CMOS circuit of the driver circuit should be covered with the resist layer 200. Using the left resist layer 200 as a mask, the active layer 24 is doped with a high concentration of impurities such as phosphorus penetrating through the gate insulating film 30. By doping regions on the active layer 24 other than the regions covered with the mask are doped with a high concentration of n type impurities, a high-concentration impurity region (N⁺ region) to be configured as a source region 24s and a drain region 24d in the subsequent process can be formed.

The resist layer 200 used as a mask is removed to expose the gate electrode 36 and then, using the exposed gate electrode 36 as a mask, the active layer 24 is doped with a low concentration of impurities such as phosphorus. Accordingly, on both sides of a region of the active layer 24 lying directly below the gate electrode 36 into which impurities are not doped, low-concentration impurity regions (N⁻ regions) are formed between the a region under the gate electrode 36 and the N⁺ region formed in the first doping process for doping high-concentration impurities. After the doping processes have been completed, annealing by irradiation with excimer laser or the like is performed to activate the impurities doped into the active layer 24.

After the activation process, an interlayer insulating film 40 is formed so as to entirely cover the substrate including the gate insulating film 30 and the gate electrode 36 formed on the substrate. The interlayer insulating film 40 is formed as described above by laminating a SiNₓ film 42 and a SiO₂ film 44, in that order from the gate insulating film 30 side, using a plasma CVD method. For this formation, in the present embodiment, the SiNₓ film 42 should be formed with a thickness greater than or equal to 50 nm and smaller than or equal to 200 nm, or more preferably with a thickness of approximately 100 nm. By forming the SiNₓ film with such thickness, a sufficient supply of hydrogen to the polycrystalline Si film (active layer) 24 during annealing for hydrogenation can be assured, and etching requirements during formation of a contact hole can be satisfied, as will be described below. The thickness of the SiO₂ film is not limited by the present embodiment and may be formed in a thickness of, for example, approximately 500 nm.

After the interlayer insulating film 40 is formed, annealing (for hydrogenation) is executed in a nitrogen atmosphere to introduce hydrogen ions contained in the SiNₓ film 42 constituting the interlayer insulating film 40 into the polycrystalline Si active layer 24 from the SiNₓ film 42 through the gate insulating film 16. The annealing temperature should be within a range in which hydrogen ions are adequately movable and the substrate 10 does not sustain damage such as thermal deformation. When the substrate is made of glass as in the case of the present embodiment, a temperature of, for example, 350° C.-450° C. is acceptable as the annealing temperature. By such annealing for hydrogenation, hydrogen is provided from the SiNₓ film 42 to the polycrystalline Si active layer 24 through the gate insulating film 30 to terminate the dangling bonds in the polycrystalline Si active layer. During hydrogenation by annealing, although almost no hydrogen transmits the gate electrode 36 formed from a metal material, hydrogen from the SiNₓ film 42 can enter the region of the active layer 24 (to be formed as a channel region in the subsequent process) above which the gate electrode 36 is placed because hydrogen is introduced to a region lying directly below the gate passing through the gate insulating film 30 from the outer of the gate electrode 36 edge. Accordingly, defect repair (termination) can be performed reliably on the channel region wielding a large influence over TFT characteristics.

After the process of annealing for hydrogenation has been completed, contact holes 46 penetrating the regions of the interlayer insulating film 40 and the gate insulating film 30 each corresponding to the source region 24s or the drain region 24d are formed. A source electrode 50s to be connected to the source region 24s and a drain electrode 50d to be connected to the drain region 24s, or integral signal wiring for the source electrode 50s and the drain electrode 50d, are formed in the contract holes 46. After the completion of the above-described processes, a thin film transistor such as shown in FIG. 1 applicable to a pixel portion or peripheral driver portions of an active matrix display apparatus can be obtained.

When the obtained thin film transistor is employed as, for example, a TFT for each pixel in an active matrix LCD, after the formation of the source/drain electrodes 50s, 50d, the thin film transistor is subjected to steps of forming a planarization insulating film so as to cover the TFT, forming a contact hole which penetrates the planarization insulating film, forming a pixel electrode of ITO or the like on the planarization insulating film, connecting the pixel electrode with either the source or drain electrode 50 via the contact hole, and forming an alignment film for controlling initial orientation of liquid crystal so as to cover the entire surface of the TFT as necessary. An element substrate thus obtained is placed so as to oppose an opposing substrate sandwiching liquid crystal in between to obtain a LCD. When the above TFT is utilized in an active matrix OEL display, for example, similarly to the LCD, an ITO pixel electrode (a first electrode which is, for example, an anode) is formed and then connected to the TFT via the contact hole. Further, organic layers including an emissive layer and a metal electrode (a second electrode which is, for example, an cathode) are formed on the ITO pixel electrode.

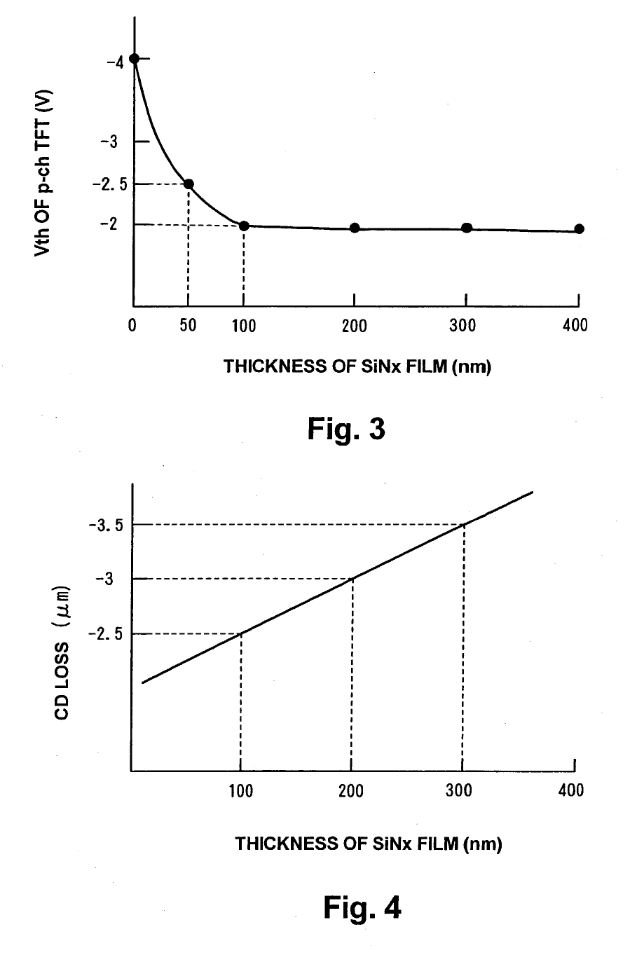

FIG. 3 shows a relationship between film thickness (nm) of the SiNₓ film 42 constituting the interlayer insulating film 40 and an operation threshold voltage (V) of a p-ch TFT in the top gate type TFT formed by the above-described processes. An operation threshold voltage Vth close to 0V is preferable for both an n-ch TFT and the p-ch TFT. However, as can be seen from FIG. 3, when the thickness of the SiNₓ film is 0 nm, i.e. only the SiO₂ film is formed, the operation threshold voltage (herein after referred to as Vth) of the p-ch TFT is −4V. On the other hand, when the thickness of the SiNₓ film is 50 nm, Vth of the p-ch TFT increases to approximately −2.5V, that is, the absolute value of Vth decreases.

One factor that causes the Vth to show a low value of −4V when the SiNₓ film is not included in the inter layer insulating film 40 is that the supply capability of hydrogen provided only by the SiO₂ film is insufficient for appropriately terminating the dangling bonds in the polycrystalline Si active layer by hydrogenation, such that the occurrence of carriers being trapped by the dangling bonds in the active layer increases. On the other hand, by forming the SiNₓ film in thickness of approximately 50 nm, Vth is considerably improved to a value of −2.5V. The value of Vth is further improved and increases as the thickness of the SiNₓ film increases. When the SiNₓ film has a thickness of 100 nm, Vth is approximately −2V. When the SiNₓ film has a thickness greater than or equal to 100 nm, Vth remains nearly constant within the a range of approximately −2V to −1.9V. As can be understood from the above description, a thickness of the SiNₓ film constituting the interlayer insulating film 40 appropriate for improving the TFT characteristics by increasing the amount of hydrogen provided to the polycrystalline Si active layer lies between approximately 50 nm and 200 nm. It can also be seen that thickness on the order of 100 nm is more preferable as thickness of the SiNₓ film in consideration of obtaining the maximum effect with the minimum film thickness.

Regarding the relationship between the thickness of the SiNₓ film and an S value of the TFT, similarly as in FIG. 3, when the thickness of the SiNₓ film lies mostly within the range of 50 nm-200 nm, or more preferably on the order of 100 nm, the greatest improvement can be obtained. Here, it should be noted that the S value is the reciprocal of inclination of subthreshold characteristic (ΔVgs), wherein the subthreshold characteristic is a change in a drain current Id relative to a gate source impressing voltage Vgs in a Vth region. Smaller S values indicate that the ON characteristic of the TFT is steep. As described above, by setting the thickness of the SiNₓ film thicker than 0 nm, more preferably almost within the range of 50 nm to 200 nm, the S value becomes small and the inclination of the subthreshold characteristic increases.

Accordingly, by forming the SiNₓ film in thickness almost within the range of 50 nm-200 nm, or more preferably with a thickness of approximately 100 nm, it becomes possible to obtain a p-ch TFT having higher Vth (close to 0V) and steeper subthreshold characteristic, which thereby in turn improves response time.

It should be noted that in FIG. 3, the Vth characteristic of p-ch TFT is evaluated because fluctuations of Vth of the p-ch TFT are larger than those of the n-ch TFT. By forming the SiNₓ film in a thickness thicker than 0 nm, or thickness of approximately 50 nm-200 nm, or more preferably with a thickness of about 100 nm, as in the case of the p-ch TFT, the S value of the n-ch TFT can be improved. In other words, the inclination of subthreshold characteristic is increased so that a TFT capable of high-speed response can be obtained.

FIG. 4 shows a relationship between the thickness (nm) of the SiNₓ film 42 constituting the interlayer insulating film 40 and CD (critical dimension) loss (μm). CD loss is represented by a distance between aperture edges of the resist mask and a material to be etched. A larger value of CD loss represents a larger difference between patterns of the mask and the material to be etched, which disadvantageously impedes realization of a highly integrated TFT and so on.

As can be seen from FIG. 4, there is proportional relationship between the thickness of the SiNₓ film and CD loss such that CD loss becomes larger as thickness increases. When the SiNₓ film 42 constituting the interlayer insulating film 40 has a thickness of 100 nm, CD loss is 2.5 μm, whereas when the thickness of the SiNₓ film 42 increases to 200 nm, CD loss increases to 3 μm, and when the thickness increases to 300 nm, CD loss increases to 3.5 μm.

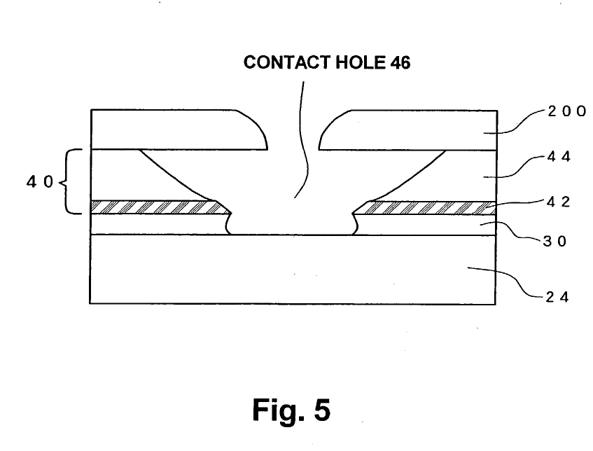

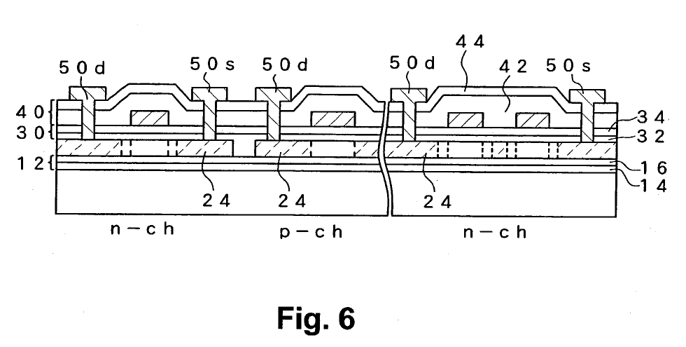

On the interlayer insulating film 40, it is necessary to form a contact hole for connecting the active layer 24 with the source/drain electrode. When CD loss is large, a contact hole having a considerably large diameter is formed, which develops a disadvantage in miniaturization of the TFT and results in declined connection reliability between the active layer 24 and the electrode wiring material in the contact hole. FIG. 5 is a schematic diagram showing an etching cross section when the contact hole is formed penetrating the SiO₂ gate insulating film formed on the polycrystalline Si active layer 24 and the interlayer insulating film 40 both comprising the SiNₓ film 42 and the SiO₂ film 44. With respect to etchant BHF for SiNₓ and SiO₂, the etching speed of the SiNₓ film is one half to one third slower that of the SiO₂ film due to the dense structure of the SiNₓ film. Further, because adhesion at an interface between the SiO₂ film 44 and the resist 200 is relatively low, the etchant diffuses along the interface between the SiO₂ film 44 and the resist 200 into the SiO₂ film, thereby etching the interface side of the SiO₂ film 44 more widely. Accordingly, when the SiNₓ film 42 has an excessive thickness, a longer time is required for etching the SiNₓ film 42, which causes that the SiO₂ film 44 formed above the SiNₓ film 42 on the resist 200 side to be etched more widely in planar direction, such that the upper diameter of the contact hole becomes larger. When the contact hole is larger in size, it is difficult to make the apparatus smaller or increase the definition of the display. Further, because the etching speed of the gate insulating film 30 comprising the SiO₂ film formed under the SiNₓ film 42 is faster than that of the SiNₓ film 42, as described above, a recess is formed in the SiO₂ face of the contact hole. Because metal materials used for establishing contact may not fill such a recessed area, the likelihood of a poor connection is increased. Accordingly, by defining thickness of the SiNₓ film constituting the interlayer insulating film 40 within the range of 50 nm-200 nm, or more preferably around 100 nm, as described above, it becomes possible to improve the TFT characteristics obtained through hydrogenation of the polycrystalline Si active layer 24 while minimizing CD loss and preventing the poor connection.

FIG. 6 shows a cross-sectional structure of a top gate type TFT according to a second embodiment of the present invention. In this embodiment, the interlayer insulating film 40 is configured by the multilayer, from the polycrystalline Si active layer 24 side, the SiNₓ film 42 having supply capability of hydrogen and the Sio₂ film 44, similarly as in the first embodiment. In the second embodiment, a buffer layer 12 having the multilayer structure is further formed between the substrate and the active layer 24 and the gate insulating film 30 also has the multilayer structure.

The buffer layer 12 is constructed by a SiNₓ film 14 and a SiO₂ film 16, in that order from the substrate side. Because the SiNₓ film is, as described above, finer than the SiO₂ film, by forming the finer SiNₓ film 14 on the substrate side, the diffusion of impurities such as sodium ions into the TFT active layer and elsewhere can be reliably prevented, even when the substrate is made of a material such as a low-cost alkali glass, such as sodalime glass. Further, because the SiO₂ film 16, which has a closer affinity for the polycrystalline Si film than does a SiNₓ film, is formed between the SiNₓ film 14 and the polycrystalline Si active layer 24, defects introduced into the polycrystalline Si active layer 24 due to distortion of the interface on the substrate side can be reduced.

The gate insulating film 30 is configured by forming a SiO₂ film 32 with a thickness of 60 nm-100 nm (for example, approximately 80 nm) and a SiNₓ film 34 with a thickness of 20 nm-60 nm (for example, approximately 40 nm), in that order from the active layer 24 side. By placing the SiO₂ film 32 on the side of the active layer 24 made of polycrystalline Si, it is possible to suppress generation of the distortion on an interface between the SiO₂ film and the active layer 24, which prevents introduction of defects to the active layer. The SiNₓ film 34 is also capable of supplying hydrogen, although the supply capacity of the SiNₓ film 34 is not as great as that of the SiNₓ film constituting the interlayer insulating film 40. The impurity-blocking capability of the SiNₓ film 34 is high and pinholes contained therein are relatively few. Further, because the gate insulating film 30 is formed in the multilayer structure, an insulation (withstanding voltage) between the active layer 24 and the gate electrode 36 can increase.

Regarding the interlayer insulating film 40 configured by laminating, from the active layer 24 side, the SiNₓ film 42 and the SiO₂ film 44, in order to secure sufficient supply capability of hydrogen and reduce CD loss, similarly as in the first embodiment, the thickness of the SiNₓ film should be set to a value almost within the range of 50 nm-200 nm, or more preferably, a value on the order of 100 nm.

As described above, by forming each of the insulating layers (the buffer layer 12, the gate insulating film 30, and the interlayer insulating film 40) to have a multilayer structure and specifying forming sequences of the buffer layer 12 as SiNₓ film—SiO₂ film, the gate insulating film 30 as the SiO₂ film—the SiNₓ film, and the interlayer insulating film 40 as the SiNₓ film—the SiO₂ film from the lower layer side, it is possible to realize a top gate type TFT capable of operating with a high degree of reliability and stability.

In the above embodiment, impurities are doped into the active layer 24 after the gate insulating film 30 and the gate electrode 36 are formed in the top gate type TFT. However, when the top gate type TFT has a LDD structure, in order to suppress acceleration energy for doping and prevent curing of a doping mask, impurities may be doped in a high concentration into a predetermined region before the gate insulating film 30 and the gate electrode 36 are formed, and then, after the gate electrode is formed, impurities may be doped in a low concentration using the gate electrode 36 as a mask. When such a manufacturing method is adopted, channel and LD regions predominantly affecting the size of a TFT area can be formed self aligning with the gate electrode 36. Even when this done, variation of the sequence for hydrogenation achieved by annealing using the SiNₓ film of the interlayer insulating film 40 as a hydrogen source is possible, and hydrogenation by annealing may be carried out after the interlayer insulating film 40 has been formed, for example, concurrently with a process for activating the doped impurities.

As has been described above, according to the embodiments of the present invention, dangling bonds in the active layer can be reliably terminated because supply of a sufficient amount of hydrogen from the SiNₓ film of the interlayer insulating film 40 is ensured, without negatively affecting etching accuracy and reliability with regard to the interlayer insulating film in the top gate type TFT using polycrystalline silicon or the like for the active layer. As a result, a TFT with improved operating characteristics is obtained.

What is claimed is:

1. A top gate type thin film transistor wherein a gate electrode is formed above an active layer, comprising:
a semiconductor film,
a gate insulating film covering said semiconductor film,
a gate electrode formed on said gate insulating film, and
an interlayer insulating film formed so as to cover said gate electrode and said gate insulating film, wherein:
said interlayer insulating film has a multilayer structure in which a silicon nitride film and a silicon oxide film are formed, in that order from a gate insulating film side; and
the thickness of said silicon nitride film is greater than or equal to 50 nm and smaller than or equal to 200 nm.

2. A top gate type thin film transistor according to claim 1, wherein the thickness of said silicon nitride is approximately 100 nm.

3. A top gate type thin film transistor according to claim 2, wherein said silicon nitride film acts as a hydrogen source for said semiconductor film made of polycrystalline silicon.

4. A top gate type thin film transistor according to claim 1, wherein said silicon nitride film acts as a hydrogen source for said semiconductor film made of polycrystalline silicon.

5. A top gate type thin film transistor wherein a gate electrode is formed above an active layer, comprising:
a buffer layer formed so as to cover a substrate,
a semiconductor film formed on said buffer layer,
a gate insulating film covering said semiconductor film,
a gate electrode formed on said gate insulating film, and
an interlayer insulating film formed so as to cover said gate electrode and said gate insulating film, wherein;
said buffer layer has a laminated structure in which a silicon nitride film and a silicon oxide film are formed, in that order from a substrate side,
said gate insulating film has a multilayer structure in which a silicon oxide film and a silicon nitride film are formed, in that order from a semiconductor side, and
said interlayer insulating film has a multilayer structure in which a silicon nitride film and a silicon oxide film are formed, in that order from a gate insulating film side.

6. A top gate type thin film transistor according to claim 5, wherein the thickness of said silicon nitride film constituting said interlayer insulating film lies within the range of 50 nm to 200 nm.
